(19) United States
(12) Patent Application Publication
(10) Pub. No.: US 2025/0393396 A1
(43) Pub. Date: Dec. 25, 2025

(54) SUB-PIXEL AND DISPLAY DEVICE INCLUDING THE SUB-PIXEL, AND ELECTRONIC DEVICE

(71) Applicant: Samsung Display Co., Ltd., Yongin-si (KR)

(72) Inventors: Se Hyun LEE, Yongin-si (KR); Kyung Bae KIM, Yongin-si (KR); Dong Woo KIM, Yongin-si (KR); Yong Hee LEE, Yongin-si (KR); Jin Joo HA, Yongin-si (KR)

(21) Appl. No.: 19/182,323

(22) Filed: Apr. 17, 2025

(30) Foreign Application Priority Data
Jun. 19, 2024 (KR) 10-2024-0079884
Jul. 16, 2024 (KR) 10-2024-0093689

(51) Int. Cl. H10K 59/121; G02B 27/01; H10H 29/32; H10H 29/49; H10K 59/131

(52) U.S. Cl. CPC H10K 59/1213; H10H 29/32; H10H 29/49; H10K 59/1216; H10K 59/131; G02B 27/0172

(57) ABSTRACT

A sub-pixel includes: a first transistor having a first electrode connected to a first power supply voltage node configured to receive a first power supply voltage via a first node, a second electrode connected to a second node, and a gate electrode connected to a third node; a light-emitting element connected between the second node and a second power supply voltage node configured to receive a second power supply voltage; a second transistor connected between a data line and the third node and having a gate electrode connected to a first sub-gate line; a first capacitor connected between the first node and the third node; a second capacitor connected between the third node and a voltage control line; and a third capacitor connected between the third node and the second node.

### CROSS-REFERENCE TO RELATED APPLICATION

The present application claims priority to and the benefit of Korean Patent Application No. 10-2024-0079884, filed on Jun. 19, 2024, and Korean Patent Application No. 10-2024-0093689, filed on Jul. 16, 2024, in the Korean Intellectual Property Office, the entire disclosures of each of which are incorporated herein by reference.

### BACKGROUND

### 1. Field

Aspects of some embodiments of the present disclosure relate to a sub-pixel and a display device including the same, and electronic device.

### 2. Description of the Related Art

As information technology advances, the role of display devices that provide a mechanism for connecting users with information is becoming increasingly important. Accordingly, the usage of display devices such as liquid crystal display devices and organic light-emitting display devices is increasing.

Recently, a sub-pixel applicable to a high-resolution panel is in demand.

The above information disclosed in this Background section is only for enhancement of understanding of the background and therefore the information discussed in this Background section does not necessarily constitute prior art.

### SUMMARY

Aspects of some embodiments of the present invention include a sub-pixel applicable to a high-resolution panel and a display device having the same.

According to some embodiments of the present invention, a sub-pixel includes: a first transistor having a first electrode connected to a first power supply voltage node configured to receive a first power supply voltage via a first node, a second electrode connected to a second node, and a gate electrode connected to a third node, a light-emitting element connected between the second node and a second power supply voltage node configured to receive a second power supply voltage, a second transistor connected between a data line and the third node and having a gate electrode connected to a first sub-gate line, a first capacitor connected between the first node and the third node, a second capacitor connected between the third node and a voltage control line and a third capacitor connected between the third node and the second node.

According to some embodiments, the voltage control line is configured to have a low-level voltage based on a data signal from the data line being supplied to the third node and to have a high-level voltage higher than the low-level voltage based on the data signal not being supplied to the third node.

According to some embodiments, the sub-pixel may further include: a third transistor connected between the first power supply voltage node and the first node and having a gate electrode connected to an emission control line, and a fourth transistor connected between the second node and an initialization voltage node configured to receive an initialization voltage and having a gate electrode connected to a second sub-gate line.

According to some embodiments, the voltage control line is configured to have a low-level voltage during a period in which the fourth transistor is turned on and to have a high-level voltage higher than the low-level voltage during a period in which the fourth transistor is turned off.

According to some embodiments, the second transistor is configured to be turned on during a part of a period in which the fourth transistor is turned on.

According to some embodiments, the first transistor, the second transistor, and the third transistor may be P-type transistors, and the fourth transistor may be an N-type transistor.

According to some embodiments, each of the first transistor to the fourth transistor includes a body electrode, and the body electrode of each of the first transistor to the third transistor is configured to receive the first power supply voltage, and the body electrode of the fourth transistor is configured to receive the initialization voltage.

According to some embodiments, each of the first transistor to the fourth transistor includes a body electrode, and the body electrode of each of the first transistor to the third transistor is configured to receive the first power supply voltage, and the body electrode of the fourth transistor is configured to receive a ground voltage.

According to some embodiments, one horizontal period is divided into a first period, a second period, and a third period, the second transistor is configured to be turned on during the first period and the second period, the fourth transistor is configured to be turned on during the first period to the third period, the third transistor is configured to be turned off during the second period, and the voltage control line has a low-level voltage during the first period to the third period and has a high-level voltage higher than the low-level voltage during other periods.

According to some embodiments, the data line is configured to receive a data signal during the first period to the third period.

According to some embodiments, the third transistor is further configured to be turned off during the first period.

According to some embodiments of the present disclosure, a display device includes: a sub-pixel connected to data lines, gate lines, and emission control lines, a gate driver configured to drive the gate lines and the emission control lines and a data driver configured to drive the data lines, wherein each of the sub-pixels comprises, a first transistor having a first electrode connected to a first power supply voltage node configured to receive a first power supply voltage via a first node, a second electrode connected to a second node, and a gate electrode connected to a third node, a light-emitting element connected between the second node and the second power supply voltage node configured to receive a second power supply voltage, a second transistor connected between a data line, which is one of the data lines, and the third node and having a gate electrode connected to a first sub-gate line, which is one of the gate lines, a first capacitor connected between the first node and the third node, a second capacitor connected between the third node and a voltage control line, which is one of the gate lines and a third capacitor connected between the third node and the second node.

According to some embodiments, each of the sub-pixels may further include: a third transistor connected between the first power supply voltage node and the first node and having a gate electrode connected to an emission control line which is one of the emission control lines and a fourth transistor connected between the second node and an initialization voltage node configured to receive an initialization voltage and having a gate electrode connected to a second sub-gate line which is one of the gate lines.

According to some embodiments, the first transistor, the second transistor, and the third transistor may be P-type transistors, and the fourth transistor may be an N-type transistor.

According to some embodiments, each of the first to fourth transistors includes a body electrode, and the body electrode of each of the first to third transistors is configured to receive the first power supply voltage, and the body electrode of the fourth transistor is configured to receive one of the initialization voltage and a ground voltage.

According to some embodiments, one horizontal period may be divided into a first period, a second period, and a third period, and the gate driver may be configured to: supply a first scan signal having a gate-on voltage to the first sub-gate line during the first period and the second period; supply a second scan signal having a gate-on voltage to the second sub-gate line during the first period to the third period; supply a low-level voltage to the voltage control line during the first period to the third period; and supply an emission control signal having a gate-off voltage to the emission control line during the second period.

According to some embodiments, the gate driver is configured to supply a high-level voltage higher than the low-level voltage to the voltage control line during a period other than the first period to the third period.

According to some embodiments, the gate driver further is configured to supply the emission control signal to the emission control line during the first period.

According to some embodiments, the data driver is configured to supply a data signal to the data line during the first period to the third period.

An electronic device according to some embodiments of the present disclosure includes: a processor to provide image data; a display device to display an image based on the image data. The display device includes: a sub-pixel connected to data lines, gate lines, and emission control lines; a gate driver for driving the gate lines and the emission control lines; and a data driver for driving the data lines, wherein each of the sub-pixels includes: a first transistor having a first electrode connected to a first power supply voltage node to which a first power supply voltage is input via a first node, a second electrode connected to a second node, and a gate electrode connected to a third node; a light-emitting element connected between the second node and the second power supply voltage node to which a second power supply voltage is input; a second transistor connected between a data line, which is one of the data lines, and the third node and having a gate electrode connected to a first sub-gate line, which is one of the gate lines; a first capacitor connected between the first node and the third node; a second capacitor connected between the third node and a voltage control line, which is one of the gate lines; and a third capacitor connected between the third node and the second node.

Aspects of embodiments according to the present disclosure are not limited to the characteristics mentioned above, and other characteristics not mentioned may be more clearly understood by those skilled in the art from the description below.

According to some embodiments of the present disclosure, in a sub-pixel and the display device including the same, the gate electrode voltage of the driving transistor may be lowered during the threshold voltage compensation period, and thus the threshold voltage compensation capability may be relatively improved. In addition, according to the sub-pixel and the display device having the same according to the embodiments of the present invention, the voltage range of the data signal (Data Swing Range) may be sufficiently secured, and accordingly, the grayscale may be relatively stably implemented. In addition, in the embodiments of the present invention, the sub-pixel may be configured using four transistors and three capacitors, and thus, it may be applied to a high-resolution panel.

However, the characteristics of embodiments according to the present disclosure are not limited to the characteristics described above and may be variously expanded within a range that does not deviate from the spirit and scope of embodiments according to the present disclosure.

### BRIEF DESCRIPTION OF THE DRAWINGS

FIG. 1 is a block diagram illustrating aspects of a display device according to some embodiments.

FIG. 2 is a block diagram illustrating aspects of one of the sub-pixels in FIG. 1 according to some embodiments.

FIG. 3 is a diagram illustrating aspects of a gate driver for driving the sub-pixel illustrated in FIG. 2 according to some embodiments.

FIG. 4 is a circuit diagram illustrating aspects of the sub-pixel in FIG. 2 according to some embodiments.

FIG. 5 is a circuit diagram illustrating aspects of the sub-pixel in FIG. 2 according to some embodiments.

FIG. 6 is a waveform diagram illustrating aspects of the method for driving the sub-pixel illustrated in FIG. 4 and FIG. 5 according to some embodiments.

FIG. 7A to FIG. 7D are diagrams illustrating aspects of the operation process of the sub-pixel corresponding to the driving waveform in FIG. 6 according to some embodiments.

FIG. 8 is a waveform diagram illustrating aspects of the method for driving the sub-pixel illustrated in FIG. 4 and FIG. 5 according to some embodiments.

FIG. 9 is a plan view illustrating aspects of the display panel in FIG. 1 according to some embodiments.

FIG. 10 is a plan view illustrating aspects of one of the pixels in FIG. 9 according to some embodiments.

FIG. 11 is a plan view illustrating aspects of one of the pixels in FIG. 9 according to some embodiments.

FIG. 12 is a block diagram illustrating aspects of a display system according to some embodiments.

FIG. 13 is a perspective view illustrating aspects of the display system in FIG. 12 according to some embodiments.

FIG. 14 is a drawing illustrating a head-mounted display device worn by a user according to some embodiments.

### DETAILED DESCRIPTION

Hereinafter, aspects of some embodiments of the present disclosure will be described in more detail with reference to the accompanying drawings. The following description is intended to provide only a sufficient disclosure to enable the understanding of the operation of the invention, and any other disclosure is omitted to avoid obscuring the scope of the invention. In addition, the inventive concept may be embodied in different forms and is not limited to the embodiments set forth herein. The embodiments described herein are provided for the purpose of describing the technical concept of the invention in sufficient detail so that those skilled in the art can easily practice it.

Throughout the specification, when it is described that an element is “connected” to another element, this includes not only being “directly connected,” but also being “indirectly connected” with another device therebetween. The terms used herein are for the purpose of describing specific embodiments and are not intended to limit the scope of the invention. Throughout the specification, unless explicitly described to the contrary, the word “comprise” and variations such as “comprises” or “comprising” may be understood to imply the inclusion of stated elements but not the exclusion of any other elements. In addition, “at least one of X, Y, and Z” and “at least one selected from the array consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, and the like may be used herein to describe various constituent elements, these constituent elements should not be limited by these terms. These terms are used to distinguish one constituent element from another. Thus, a first constituent element discussed below could be termed a second constituent element without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of a device in use, operation, and/or manufacture in addition to the orientation depicted in the drawings. For example, if the device in the drawings is turned over, elements described as “below” or “beneath” other elements or features would then be oriented “above” the other elements or features. Thus, the term “below” can encompass both an orientation of above and below. Furthermore, the device may be otherwise oriented (e.g., rotated 90 degrees or at other orientations), and, as such, the spatially relative descriptors used herein are interpreted accordingly.

Various embodiments are described herein with reference to sectional illustrations that are schematic illustrations of idealized embodiments. As such, variations from the shapes of the illustrations as a result, for example, of manufacturing techniques and/or tolerances, are to be expected. Thus, the embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

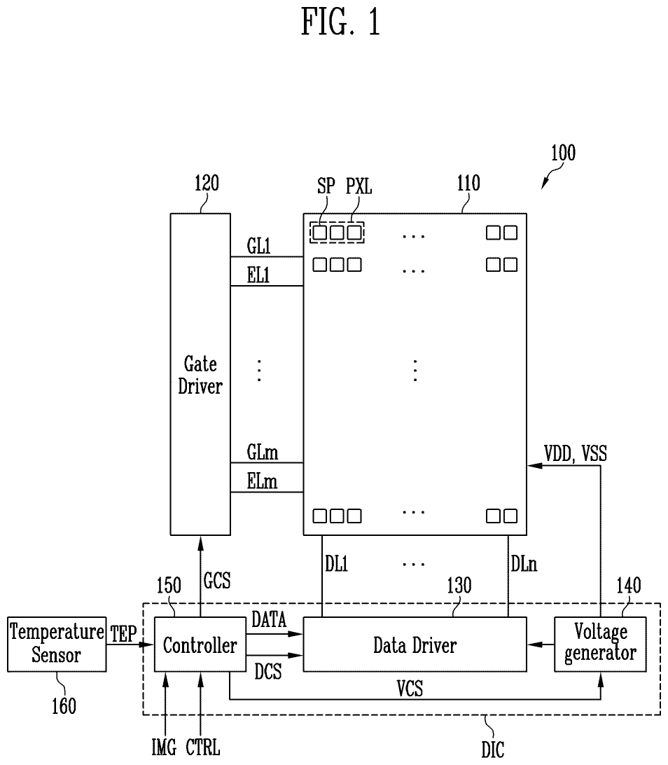

FIG. 1 is a block diagram illustrating aspects of a display device according to some embodiments.

Referring to FIG. 1, a display device 100 may include a display panel 110, a gate driver 120, a data driver 130, a voltage generator 140, and a controller 150.

The display panel 110 includes a plurality of sub-pixels SP. The sub-pixels SP may be connected to the gate driver 120 through the first to m-th gate lines GL1 to GLm. The sub-pixels SP may be connected to the data driver 130 through first to n-th data lines DL1 to DLn.

Each of the sub-pixels SP may include at least one light-emitting element configured to generate light. Accordingly, each of the sub-pixels SP may generate light of a specific color, such as red, green, blue, cyan, magenta, yellow, and the like. Two or more sub-pixels among the sub-pixels SP may constitute one pixel PXL. For example, as illustrated in FIG. 1, three sub-pixels may constitute one pixel PXL. Collectively, the pixels PXL, and their corresponding sub-pixels SP, may display images based on data signals and gate/scan signals.

The gate driver 120 is connected to the sub-pixels SP arranged in the row direction through the first to m-th gate lines GL1 to GLm. The gate driver 120 may output scan signals to the first to m-th gate lines GL1 to GLm in response to the gate control signal GCS. According to some embodiments, the gate control signal GCS may include a start signal indicating the start of each frame, a horizontal synchronization signal for outputting scan signals in synchronization with the timing at which data signals are applied, and other signals.

According to some embodiments, first to m-th emission control lines EL1 to ELm connected to the sub-pixels SP in the row direction may be further provided. In this case, the gate driver 120 may include an emission driver configured to control the first to m-th emission control lines EL1 to ELm, and the emission driver may operate under the control of the controller 150.

The gate driver 120 may be arranged on one side of the display panel 110. However, the embodiments are not limited thereto. For example, the gate driver 120 may be divided into two or more drivers that are physically and/or logically separated, and such drivers may be arranged on one side of the display panel 110 and the other side of the display panel 110 opposite to the one side. In this way, the gate driver 120 may be arranged on the periphery of the display panel 110 in various forms according to various embodiments.

The data driver 130 is connected to the sub-pixels SP arranged in the column direction through the first to n-th data lines DL1 to DLn. The data driver 130 receives image data DATA and a data control signal DCS from the controller 150. The data driver 130 operates in response to the data control signal DCS. According to some embodiments, the data control signal DCS may include a source start pulse, a source shift clock, a source output enable signal, and other signals.

The data driver 130 may apply data signals having grayscale voltages corresponding to the image data DATA to the first to n-th data lines DL1 to DLn using voltages from the voltage generator 140. When a scan signal is applied to each of the first to m-th gate lines GL1 to GLm, data signals corresponding to the image data DATA may be applied to the data lines DL1 to DLn. Accordingly, the corresponding sub-pixels SP may generate light corresponding to the data signals. Accordingly, an image is displayed on the display panel 110.

According to some embodiments, the gate driver 120 and the data driver 130 may include CMOS (complementary metal-oxide semiconductor) circuit elements.

The voltage generator 140 may operate in response to a voltage control signal VCS from the controller 150. The voltage generator 140 is configured to generate a plurality of voltages and provide the generated voltages to the components of the display device 100. For example, the voltage generator 140 may be configured to receive an input voltage from outside the display device 100, adjust the received voltage, and generate a plurality of voltages by regulating the adjusted voltage.

The voltage generator 140 may generate a first power supply voltage VDD and a second power supply voltage VSS, and the generated first and second power supply voltages VDD and VSS may be provided to the sub-pixels SP. The first power supply voltage VDD may have a relatively high voltage level, and the second power supply voltage VSS may have a lower voltage level than the first power supply voltage VDD. According to some embodiments, the first power supply voltage VDD or the second power supply voltage VSS may be provided by an external device of the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light-emitting elements of the sub-pixels SP, a predetermined reference voltage may be applied to the first to n-th data lines DL1 to DLn, and the voltage generator 140 may generate such a reference voltage.

The controller 150 controls all operations of the display device 100. The controller 150 receives input image data IMG from the outside and a control signal CTRL for controlling its display. The controller 150 may provide a gate control signal GCS, a data control signal DCS, and a voltage control signal VCS in response to the control signal CTRL.

The controller 150 may convert input image data IMG to be suitable for the display device 100 or the display panel 110 and output image data DATA. According to some embodiments, the controller 150 may align the input image data IMG to be suitable for the row-level sub-pixels SP and output image data DATA.

Two or more components among the data driver 130, the voltage generator 140, and the controller 150 may be mounted on a single integrated circuit. As illustrated in FIG. 1, the data driver 130, the voltage generator 140, and the controller 150 may be included in a driver-integrated circuit DIC. In this case, the data driver 130, the voltage generator 140, and the controller 150 may be functionally separated components within a single driver-integrated circuit DIC. According to some embodiments, at least one of the data driver 130, the voltage generator 140, or the controller 150 may be provided as a separate component from the driver-integrated circuit DIC.

The display device 100 may include at least one temperature sensor 160. The temperature sensor 160 is configured to detect a temperature in its surroundings and generate temperature data TEP representing the detected temperature. According to some embodiments, the temperature sensor 160 may be arranged adjacent to the display panel 110 and/or the driver-integrated circuit DIC.

The controller 150 may control various operations of the display device 100 in response to the temperature data TEP. According to some embodiments, the controller 150 may adjust the brightness of an image output from the display panel 110 in response to the temperature data TEP. For example, the controller 150 may control the data signals and the first and second power supply voltages VDD and VSS by controlling components such as the data driver 130 and/or the voltage generator 140.

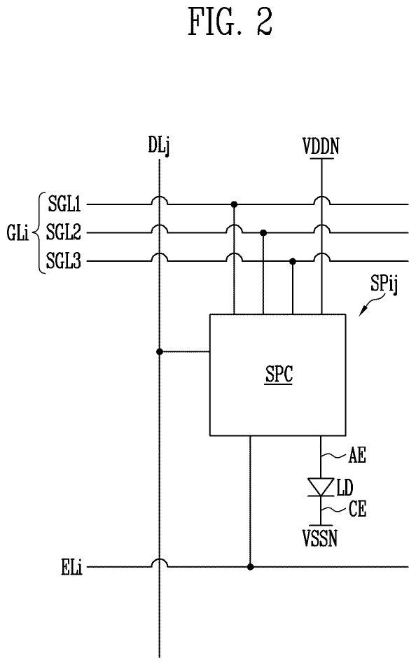

FIG. 2 is a block diagram illustrating aspects of one of the sub-pixels in FIG. according to some embodiments. In FIG. 2, a sub-pixel SPij arranged in an i-th row (i is an integer of 1 or more and m or less) and a j-th column (j is an integer of 1 or more and n or less) among the sub-pixels SP in FIG. 1 is illustrated as an example.

Referring to FIG. 2, the sub-pixel SPij may include a sub-pixel circuit SPC and a light-emitting element LD.

The light-emitting element LD is connected between the first power supply voltage node VDDN and the second power supply voltage node VSSN. At this time, the first power supply voltage node VDDN is a node that transmits the first power supply voltage VDD in FIG. 1, and the second power supply voltage node VSSN is a node that transmits the second power supply voltage VSS in FIG. 1.

The anode electrode AE of the light-emitting element LD may be connected to the first power supply voltage node VDDN through the sub-pixel circuit SPC, and the cathode electrode CE of the light-emitting element LD may be connected to the second power supply voltage node VSSN. For example, the anode electrode AE of the light-emitting element LD may be connected to the first power supply voltage node VDDN through one or more transistors included in the sub-pixel circuit SPC.

The sub-pixel circuit SPC may be connected to the i-th gate line GLi among the first to m-th gate lines GL1 to GLm in FIG. 1, the i-th emission control line ELi among the first to m-th emission control lines EL1 to ELm in FIG. 1, and the j-th data line DLj among the first to n-th data lines DL1 to DLn in FIG. 1. The sub-pixel circuit SPC is configured to control the light-emitting element LD according to signals received through these signal lines.

The sub-pixel circuit SPC may operate in response to a scan signal received through the i-th gate line GLi. The i-th gate line GLi may include one or more sub-gate lines. According to some embodiments, as illustrated in FIG. 2, the i-th gate line GLi may include a first sub-gate line SGL1, a second sub-gate line SGL2, and a third sub-gate line SGL3 (or a voltage control line). The sub-pixel circuit SPC may operate in response to scan signals received through the first to third sub-gate lines SGL1, SGL2, and SGL3. In this way, when the i-th gate line GLi includes two or more sub-gate lines, the sub-pixel circuit SPC may operate in response to scan signals received through the corresponding sub-gate lines.

The sub-pixel circuit SPC may operate in response to an emission control signal received through the i-th emission control line ELi. According to some embodiments, the i-th emission control line ELi may include one or more sub-emission control lines. When the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the scan signals received through the first to third sub-gate lines SGL1, SGL2, or SGL3. The sub-pixel circuit SPC may control a current flowing from the first power supply voltage node VDDN to the second power supply voltage node VSSN through the light-emitting element LD according to the stored voltage in response to the emission control signal received through the i-th emission control line ELi. Accordingly, the light-emitting element LD may generate light having a brightness corresponding to the data signal.

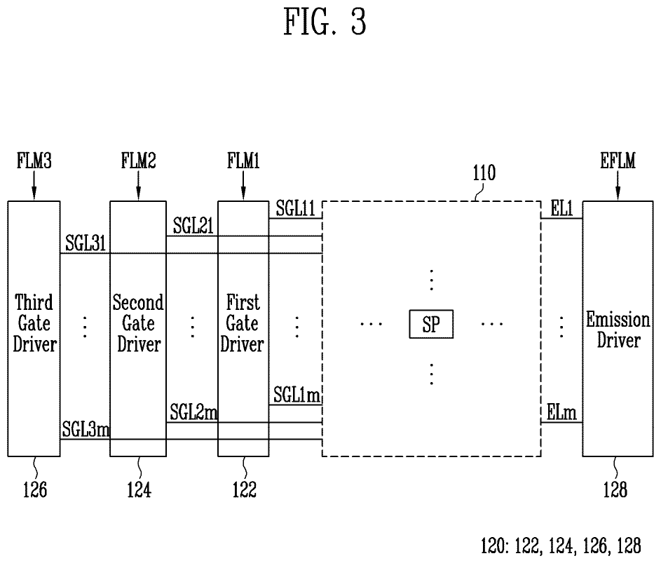

FIG. 3 is a drawing illustrating aspects of a gate driver for driving the sub-pixel illustrated in FIG. 2 according to some embodiments. The gate control signal GCS may include a first scan start signal FLM1, a second scan start signal FLM2, a third scan start signal FLM3, and an emission start signal EFLM. According to some embodiments, the gate control signal GCS may include clock signals.

Referring to FIG. 3, the gate driver 120 may include a first gate driver 122, a second gate driver 124, a third gate driver 126, and an emission driver 128.

The first gate driver 122 may receive the first scan start signal FLM1 and generate a first scan signal while shifting the first scan start signal FLM1 in response to the clock signal. The first gate driver 122 may sequentially supply the first scan signal to the first sub-gate lines SGL11 to SGL1m.

The second gate driver 124 may receive the second scan start signal FLM2 and generate the second scan signal while shifting the second scan start signal FLM2 in response to the clock signal. The second gate driver 124 may sequentially supply the second scan signal to the second sub-gate lines SGL21 to SGL2m.

The third gate driver 126 may receive the third scan start signal FLM3 and generate the third scan signal while shifting the third scan start signal FLM3 in response to the clock signal. The third gate driver 126 may sequentially supply the third scan signal to the third sub-gate lines SGL31 to SGL3m.

The first scan signal (or enable first scan signal) and the second scan signal (or enable second scan signal) may be set to a gate-on voltage so that the transistors included in the sub-pixels SP can be turned on.

For example, a scan signal of a logic low level may be supplied to a P-type transistor, and a scan signal of a logic high level may be supplied to an N-type transistor. According to some embodiments, the first scan signal may be a logic low level, and the second scan signal may be a logic high level. The transistor supplied with the first scan signal or the second scan signal may be turned on in response to the first scan signal or the second scan signal. Hereinafter, the supply of the first scan signal and the second scan signal may mean that the gate-on voltage is supplied to the sub-gate lines SGL11 to SGL1m and SGL21 to SGL2m.

The third scan signal may be supplied to a capacitor included in the sub-pixel SP. The third scan signal may be set to a low-level voltage during a period in which the voltage of the data signal is supplied to the sub-pixel SP, and may be set to a high-level voltage higher than the low-level voltage during other periods.

Additionally, the first sub-gate line SGL1 illustrated in FIG. 2 may be any one of the first sub-gate lines SGL11 to SGL1m. The second sub-gate line SGL2 illustrated in FIG. 2 may be any one of the second sub-gate lines SGL21 to SGL2m. The third sub-gate line SGL3 illustrated in FIG. 2 may be any one of the third sub-gate lines SGL31 to SGL3m.

The emission driver 128 may generate an emission control signal while shifting the emission start signal EFLM in response to a clock signal. The emission driver 128 may sequentially supply a disable emission control signal to the emission control lines EL1 to ELm. The disable emission control signal may be set to a gate-off voltage so that the transistors included in the sub-pixels SP can be turned off.

For example, a disable emission control signal of a logic high level may be supplied to a P-type transistor, and a disable emission control signal of a logic low level may be supplied to an N-type transistor. According to some embodiments, the disable emission control signal may be a logic high level. A transistor that receives the disable emission control signal may be turned off in response to the emission control signal.

The emission driver 126 may supply an enable emission control signal during a period when a disable emission control signal is not supplied to the emission control lines EL1 to ELm. The enable emission control signal may be set to a gate-on voltage so that a transistor included in the sub-pixels SP can be turned on.

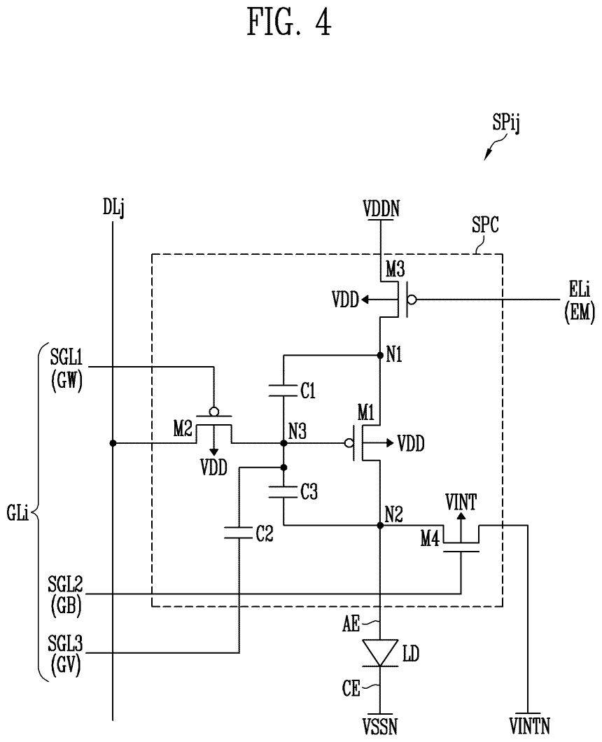

FIG. 4 is a circuit diagram illustrating aspects of the sub-pixel in FIG. 2 according to some embodiments. Although FIG. 4 illustrates various components in a sub-pixel according to some embodiments, embodiments according to the present disclosure are not limited thereto, and according to some embodiments, the sub-pixel may include additional components or fewer components without departing from the spirit and scope of embodiments according to the present disclosure.

Referring to FIG. 4, the sub-pixel SPij may include a sub-pixel circuit SPC and a light-emitting element LD.

The light-emitting element LD may include an anode electrode AE, a cathode electrode CE, and a light-emitting layer. The light-emitting layer may be arranged between the anode electrode AE and the cathode electrode CE. The anode electrode AE of the light-emitting element LD may be electrically connected to the first power supply voltage node VDDN via the second node N2, the first transistor M1, the first node N1, and the third transistor M3, and the cathode electrode CE of the light-emitting element LD may be electrically connected to the second power supply voltage node VSSN. The light-emitting element LD may generate light of a predetermined brightness in response to the amount of current supplied from the first power supply voltage node VDDN to the second power supply voltage node VSSN via the sub-pixel circuit SPC.

The light-emitting element LD may be an organic light-emitting diode. According to some embodiments, the light-emitting element LD may be an inorganic light-emitting diode such as a micro-LED (light-emitting diode) or a quantum dot light-emitting diode. According to some embodiments, the light-emitting element LD may be a composite element composed of organic and inorganic materials. In FIG. 4, the sub-pixel SPij is illustrated as including a single light-emitting element LD. However, according to some embodiments, the sub-pixel SPij includes a plurality of light-emitting elements LD, and the plurality of light-emitting elements LD may be connected to each other in series, in parallel, or in series-parallel.

The sub-pixel circuit SPC may include a first transistor M1, a second transistor M2, a third transistor M3, a fourth transistor M4, a first capacitor C1, a second capacitor C2, and a third capacitor C3.

The first transistor M1 to the fourth transistor M4 may be MOSFETs including a body electrode. In this case, the first transistor M1 to the fourth transistor M4 may be mounted in a narrow area, and thus, the sub-pixel SPij may be applied to a high-resolution panel.

According to some embodiments, the first transistor M1 to the third transistor M3 may be P-type transistors, and the fourth transistor M4 may be N-type transistors. A first power supply voltage VDD may be supplied to each of the body electrodes of the first transistor M1 to the third transistor M3, and an initialization voltage VINT may be supplied to the body electrode of the fourth transistor M4.

The first electrode of the first transistor M1 may be connected to the first node N1, and the second electrode may be connected to the second node N2. Here, being connected includes the meaning of being electrically connected. The gate electrode of the first transistor M1 may be connected to the third node N3. The first node N1 may mean a node to which the second electrode of the third transistor M3 is connected, and the second node N2 may mean a node to which the anode electrode AE of the light-emitting element LD is connected. The first transistor M1 may control the amount of current supplied from the first power supply voltage node VDDN to the second power supply voltage node VSSN via the light-emitting element LD in response to the voltage of the third node N3.

The second transistor M2 may be connected between the data line DLj and the third node N3. The gate electrode of the second transistor M2 may be electrically connected to the first sub-gate line SGL1. Such a second transistor M2 may be turned on when the first scan signal GW is supplied to the first sub-gate line SGL1 to electrically connect the data line DLj and the third node N3.

The first electrode of the third transistor M3 may be electrically connected to the first power supply voltage node VDDN, and the second electrode may be connected to the first node N1. The gate electrode of the third transistor M3 may be electrically connected to the emission control line ELi. Such a third transistor M3 may be turned off when a disable emission control signal is supplied to the emission control line ELi, and may be turned on when an enable emission control signal is supplied. When the third transistor M3 is turned off, the first power supply voltage node VDDN and the first node N1 may be electrically disconnected.

The first electrode of the fourth transistor M4 may be connected to the second node N2, and the second electrode may be electrically connected to the initialization voltage node VINTN. The initialization voltage node VINTN may be configured to transmit the initialization voltage VINT. The initialization voltage VINT may be provided by the voltage generator 140 in FIG. 1. The initialization voltage VINT may be set to a voltage at which the light-emitting element LD is turned off when supplied to the anode electrode AE of the light-emitting element LD. The fourth transistor M4 may be turned on when the second scan signal GB is supplied to the second sub-gate line SGL2 to electrically connect the second node N2 and the initialization voltage node VINTN.

The first capacitor C1 may be connected between the first node N1 and the third node N3. The first capacitor C1 may be driven as a coupling capacitor and may transfer the amount of change in voltage of the first node N1 to the third node N3. According to some embodiments, the first capacitor C1 may store the voltage of the third node N3.

The first electrode of the second capacitor C2 may be connected to the third node N3, and the second electrode may be connected to the third sub-gate line SGL3 (or voltage control line). The second capacitor C2 may be driven by a coupling capacitor and may control the voltage of the third node N3 in response to the voltage of the third scan signal GV supplied to the third sub-gate line SGL3.

The first electrode of the third capacitor C3 may be connected to the third node N3, and the second electrode may be connected to the second node N2. The third capacitor C3 may be driven by a coupling capacitor and may transmit the amount of change in voltage of the second node N2 to the third node N3.

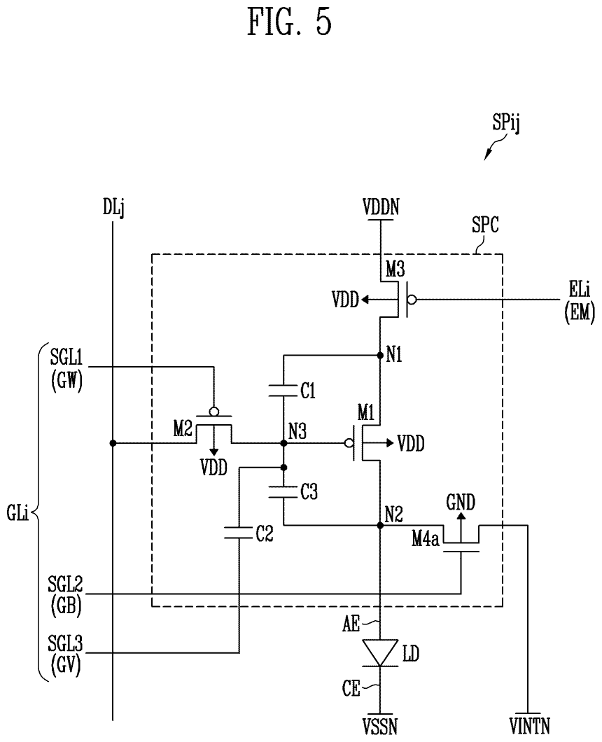

FIG. 5 is a circuit diagram illustrating aspects of the sub-pixel in FIG. 2 according to some embodiments. Although FIG. 5 illustrates various components in a sub-pixel according to some embodiments, embodiments according to the present disclosure are not limited thereto, and according to some embodiments, the sub-pixel may include additional components or fewer components without departing from the spirit and scope of embodiments according to the present disclosure.

When explaining FIG. 5, the same reference numerals are assigned to the same configuration as FIG. 4, and some redundant descriptions may be omitted.

Referring to FIG. 5, the sub-pixel circuit SPC may include a first transistor M1, a second transistor M2, a third transistor M3, a fourth transistor M4a, a first capacitor C1, a second capacitor C2, and a third capacitor C3.

The fourth transistor M4a may be connected between the second node N2 and the initialization voltage node VINTN. The gate electrode of the fourth transistor M4a may be connected to the second sub-gate line SGL2. According to some embodiments, the body electrode of the fourth transistor M4a may be supplied with a ground voltage GND. The fourth transistor M4 may be turned on when the second scan signal GB is supplied to the second sub-gate line SGL2 to electrically connect the second node N2 and the initialization voltage node VINTN.

The sub-pixel SPij illustrated in FIG. 5 may be substantially the same as the sub-pixel SPij illustrated in FIG. 4, except that the ground voltage GND is supplied to the body electrode of the fourth transistor M4a.

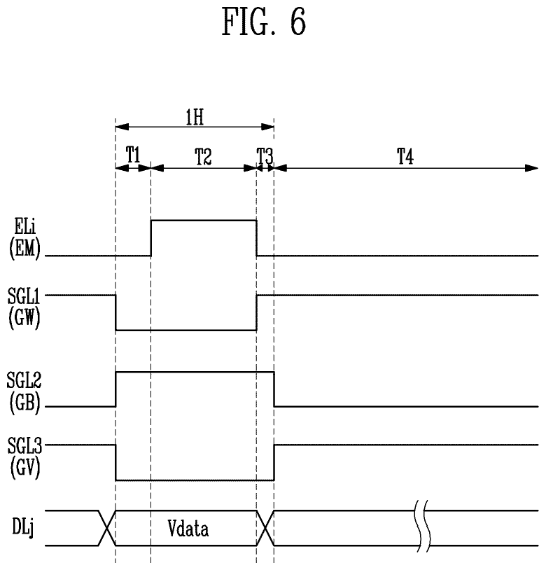

FIG. 6 is a waveform diagram illustrating an example of a method for driving the sub-pixel illustrated in FIGS. 4 and 5.

Referring to FIG. 6, the horizontal period 1H (or a specific horizontal period) in which the sub-pixel SPij is driven may be divided into a first period T1, a second period T2, and a third period T3.

The data driver 130 may supply the voltage Vdata of the data signal to the data line DLj during the first period T1 to the third period T3.

The gate driver 120 (or the first gate driver 122) may supply the first scan signal GW to the first sub-gate line SGL1 during the first period T1 and the second period T2. The first scan signal GW may be a logic low level.

The gate driver 120 (or the second gate driver 124) may supply the second scan signal GB to the second sub-gate line SGL2 during the first period T1 to the third period T3. The second scan signal GB may be a logic high level.

The gate driver 120 (or the third gate driver 126) may supply a third scan signal GV to the third sub-gate line SGL3 during the first period T1 to the third period T3. The third scan signal GV may be a low-level voltage.

The gate driver 120 (or the emission driver 128) may supply a disable emission control signal EM to the emission control line ELi during the second period T2. The disable emission control signal EM may be a logic high level.

The first period T1 is a period in which a first power supply voltage VDD is supplied to the first node N1, an initialization voltage VINT is supplied to the second node N2, and a voltage Vdata of a data signal is supplied to the third node N3. During the first period T1, the light-emitting element LD may be initialized. During the first period T1, the first capacitor C1, the second capacitor C2, and the third capacitor C3 may be initialized. This first period T1 may be called an initialization period.

The second period T2 is a period in which an initialization voltage VINT is supplied to the second node N2 and a voltage Vdata of a data signal is supplied to the third node N3. During the second period T2, a voltage corresponding to the threshold voltage of the first transistor M1 may be stored in the first capacitor C1. This second period T2 may be called a data writing/threshold voltage compensation period.

During the third period T3, the first transistor M1 may control the amount of current supplied from the first power supply voltage VDD to the initialization voltage VINT in response to the voltage of the third node N3. In this case, unnecessary current may be prevented from being supplied to the light-emitting element LD after the second period T2. This third period T3 may be called a brightness control period.

During the fourth period T4, the first transistor M1 may control the amount of current supplied from the first power supply voltage node VDDN to the second power supply voltage node VSSN through the light-emitting element LD in response to the voltage of the third node N3. During the fourth period T4, the light-emitting element LD may emit light with a brightness corresponding to the amount of current supplied from the first transistor M1. This fourth period T4 may be called an emission period.

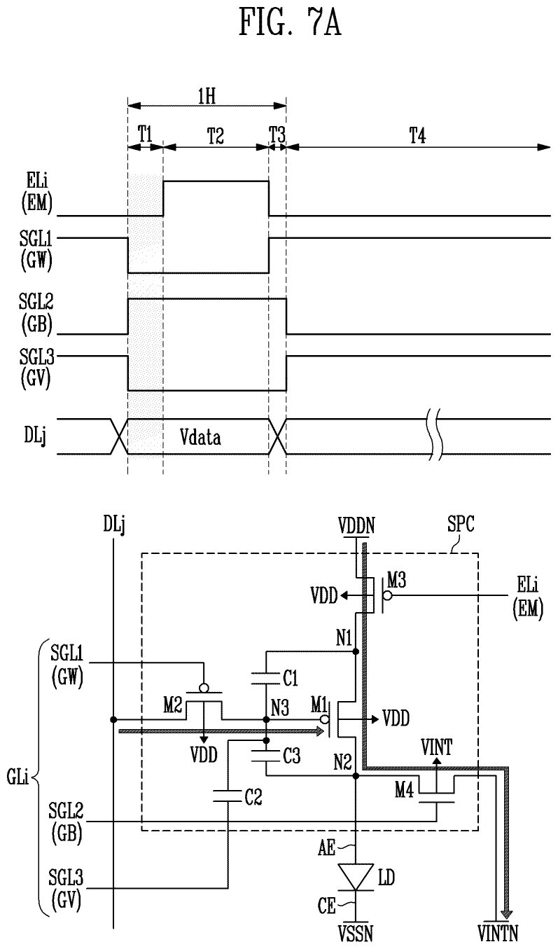

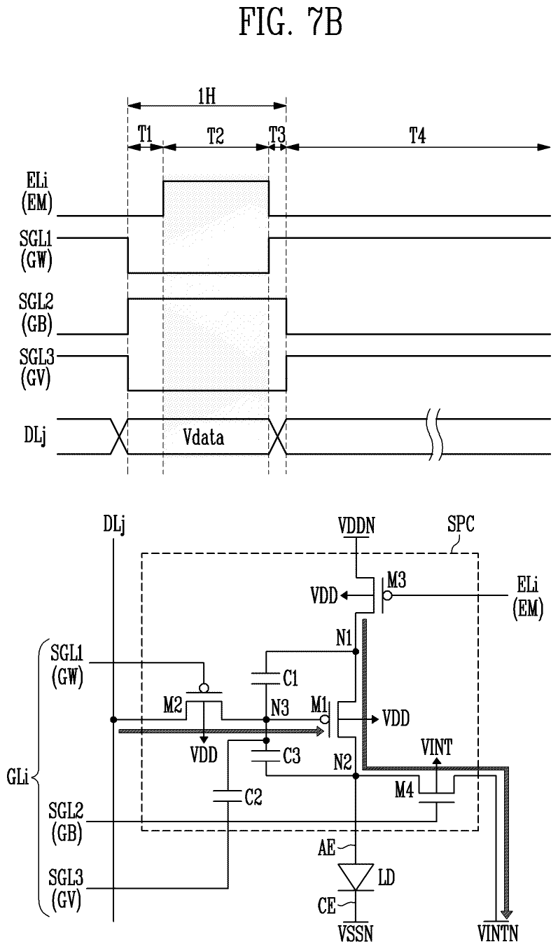

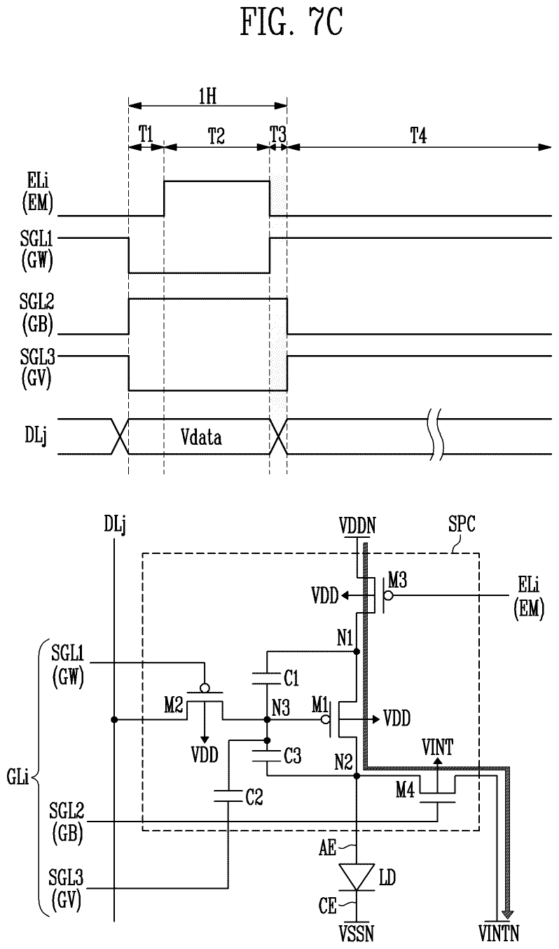

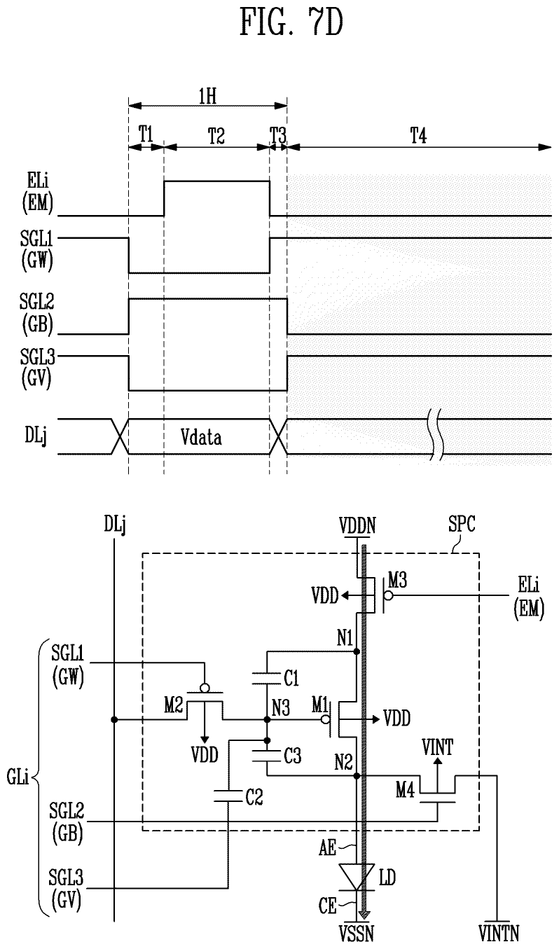

FIGS. 7A to 7D are drawings illustrating an example of the operation process of a sub-pixel corresponding to the driving waveform in FIG. 6. In FIGS. 7A to 7D, the operation process is explained using the sub-pixel SPij illustrated in FIG. 4, but the operation of the sub-pixel SPij illustrated in FIG. 5 may be substantially the same.

Referring to FIG. 7A, a first scan signal GW is supplied to a first sub-gate line SGL1 during a first period T1, and a second scan signal GB is supplied to a second sub-gate line SGL2. A third scan signal GV is supplied to a third sub-gate line SGL3 during the first period T1. According to some embodiments, an enable emission control signal EM is supplied to an emission control line ELi during a first period T1, and accordingly, a third transistor M3 is set to a turn-on state. When the third transistor M3 is set to a turn-on state, the first power supply voltage VDD may be supplied to the first node N1.

When the third scan signal GV is supplied to the third sub-gate line SGL3, the voltage of the second electrode of the second capacitor C2 is set to a low level. For example, the voltage of the second electrode of the second capacitor C2 may be set to a low level during the first period T1 to the third period T3 in response to the third scan signal GV.

That is, the third sub-gate line SGL3 may have a low-level voltage during the period in which the voltage Vdata of the data signal from the data line DLj is supplied to the third node N3. The third sub-gate line SGL3 may have a high-level voltage for at least a portion of a period when the voltage Vdata of the data signal from the data line DLj is not supplied to the third node N3, for example, after the second transistor M2 is turned off.

The third sub-gate line SGL3 may have a low-level voltage during a period when the fourth transistor M4 is turned on, and may have a high-level voltage during a period when the fourth transistor M4 is turned off.

When the first scan signal GW is supplied to the first sub-gate line SGL1, the second transistor M2 is turned on. When the second transistor M2 is turned on, the voltage Vdata of the data signal from the data line DLj is supplied to the third node N3.

The first capacitor C1 may be initialized by the voltage Vdata of the data signal and the first power supply voltage VDD. For example, the first capacitor C1 may charge the voltage corresponding to the voltage Vdata of the data signal and the first power supply voltage VDD regardless of the voltage charged in the previous period (or the previous frame period) during the first period T1.

The second capacitor C2 may be initialized by the voltage Vdata of the data signal and the voltage (that is, the low-level voltage) of the third scan signal GV. For example, the second capacitor C2 may charge the voltage corresponding to the voltage Vdata of the data signal and the third scan signal GV regardless of the voltage charged in the previous period (or the previous frame period) during the first period T1.

When the second scan signal GB is supplied to the second sub-gate line SGL2, the fourth transistor M4 is turned on. When the fourth transistor M4 is turned on, the initialization voltage VINT is supplied to the second node N2. When the initialization voltage VINT is supplied to the second node N2, the light-emitting element LD may be initialized. For example, when the initialization voltage VINT is supplied to the second node N2, the parasitic capacitor of the light-emitting element LD may be discharged.

The third capacitor C3 may be initialized by the voltage Vdata of the data signal supplied to the third node N3 and the initialization voltage VINT supplied to the second node N2. For example, the third capacitor C3 may charge a voltage corresponding to the voltage Vdata of the data signal and the initialization voltage VINT regardless of the voltage charged in the previous period (or the previous frame period) during the first period T1.

The current supplied from the first transistor M1 during the first period T1 may be supplied to the initialization voltage node VINTN via the fourth transistor M4. Therefore, the light-emitting element LD may maintain a non-emission state during the first period T1.

Referring to FIG. 7B, during the second period T2, the second transistor M2 may be maintained in a turn-on state by the first scan signal GW supplied to the first sub-gate line SGL1, and the fourth transistor M4 may be maintained in a turn-on state by the second scan signal GB supplied to the second sub-gate line SGL2.

During the second period T2, the third transistor M3 may be turned off by the disable emission control signal EM supplied to the emission control line ELi. When the third transistor M3 is turned off, the first power supply voltage node VDDN and the first node N1 may be electrically disconnected.

Since the second transistor M2 is set to the turn-on state during the second period T2, the voltage Vdata of the data signal is supplied to the third node N3 from the data line DLj. In this case, the voltage of the first node N1 may be lowered from the first power supply voltage VDD to the voltage (Vdata+|Vth(M1)|) which is the sum of the absolute threshold voltage of the first transistor M1 and the voltage Vdata of the data signal.

That is, during the second period T2, the third node N3 may be set to the voltage Vdata of the data signal, and the first node N1 may be set to the voltage (Vdata+|Vth(M1)|) which is the sum of the voltage Vdata of the data signal and the absolute threshold voltage of the first transistor M1. Therefore, the threshold voltage of the first transistor M1 may be stored in the first capacitor C1 during the second period T2.

Since the fourth transistor M4 is set to a turn-on state during the second period T2, the current supplied from the first node N1 to the second node N2 via the first transistor M1 may be supplied to the initialization voltage node VINTN via the fourth transistor M4. Therefore, the light-emitting element LD may maintain a non-emission state during the second period T2.

Referring to FIG. 7C, during the third period T3, an enable emission control signal EM is supplied to the emission control line ELi, and accordingly, the third transistor M3 may be set to a turn-on state. During the third period T3, the supply of the first scan signal GW to the first sub-gate line SGL1 is stopped, and accordingly, the second transistor M2 may be set to a turn-off state. During the third period T3, the second scan signal GB is supplied to the second sub-gate line SGL2, and accordingly, the fourth transistor M4 maintains a turn-on state.

Since the third transistor M3 is set to a turn-on state during the third period T3, the first transistor M1 controls the amount of current supplied from the first power supply voltage VDD to the second node N2 in response to the voltage of the third node N3. At this time, since the fourth transistor M4 is set to the turn-on state, the current supplied to the second node N2 may be supplied to the initialization voltage node VINTN. That is, during the third period T3, the light-emitting element LD is set to a non-emission state, and thus, the grayscale expressiveness of the display device 100 may be relatively improved.

In detail, during the second period T2, the voltage of the second node N2 may rise to a voltage higher than the desired voltage, and thus, unnecessary current may be supplied to the light-emitting element LD. For example, even when implementing a grayscale of black in the sub-pixel SPij, the light-emitting element LD may temporarily emit light. Therefore, according to some embodiments of the present invention, the current supplied from the first transistor M1 during the third period T3 is supplied to the initialization power Vint, and thus, the grayscale expressiveness of the display device 100 may be relatively improved.

During the third period T3, the voltage of the first node N1 may be changed from the voltage (Vdata+|Vth(M1)|) which is the sum of the voltage Vdata of the data signal and the absolute threshold voltage of the first transistor M1 to the first power supply voltage VDD. Accordingly, the amount of change in the voltage of the first node N1 may be expressed as in Math. 1.

$$Δ VN 1 = ELVDD - ( Vdata + \vert Vth \vert ) \qquad Math . 1$$

In Math. 1, ΔVN1 may represent the amount of change in voltage of the first node N1. When the voltage of the first node N1 changes as in Math. 1 during the third period T3, the voltage of the third node N3 may change as in Math. 2 due to the coupling of the first capacitor C1.

$$VN 3 = Vdata + \frac{C 1}{C 1 + C 2 + C 3} \times ( ELDD - ( Vdata + \vert Vth \vert ) ) \qquad Math . 2$$

In Math. 2, VN3 may represent the voltage of the third node N3. The voltage of the third node N3 may change by the value obtained by multiplying the amount of change in voltage of the first node N1 by the ratio of the capacitors C1, C2, and C3 (for example, C1/(C1+C2+C3)).

Referring to FIG. 7D, during the fourth period T4, the supply of the second scan signal GB to the second sub-gate line SGL2 is interrupted, and accordingly, the fourth transistor M4 may be turned off. During the fourth period T4, the first scan signal GW is not supplied to the first sub-gate line SGL1, and accordingly, the second transistor M2 maintains a turn-off state. During the fourth period T4, the enable emission control signal EM is supplied to the emission control line ELi, and accordingly, the third transistor M3 may maintain a turn-on state.

During the fourth period T4, the supply of the third scan signal GV to the third sub-gate line SGL3 is interrupted, and accordingly, the voltage of the third sub-gate line SGL3 rises to a high level. That is, during the fourth period T4, the voltage of the third sub-gate line SGL3 rises from a low level to a high level, and the voltage of the third node N3 may also rise due to the coupling of the second capacitor C2.

At this time, the first transistor M1 controls the amount of current supplied from the first power supply voltage node VDDN to the second power supply voltage node VSSN via the light-emitting element LD in response to the voltage of the third node N3. During the fourth period T4, the light-emitting element LD may generate light with a brightness corresponding to the amount of driving current supplied from the first transistor M1.

During the fourth period T4, the voltage of the second node N2 may be changed from the initialization voltage VINT to a predetermined voltage. The amount of change in the voltage of the second node N2 during the fourth period T4 may be expressed as in Math. 3.

$$Δ VN 2 = VN 2 - VINT \qquad Math . 3$$

In Math. 3, ΔVN2 may represent the amount of change in voltage of the second node N2, and VN2 may represent the voltage of the second node N2 during the fourth period T4. The amount of change in voltage of the third node N3 by the second capacitor C2 and the amount of change in voltage of the third node N3 by the third capacitor C3 during the fourth period T4 may be expressed as Math. 4.

$$VN {3}^{′} = VN 3 + Δ VN 2 \times \frac{C 3}{C 1 + C 2 + C 3} + Δ SGL 3 \times \frac{C 2}{C 1 + C 2 + C 3} \qquad Math . 4$$

In Math. 4, VN3′ may represent the voltage of the third node N3 in the fourth period T4, VN3 may represent the voltage of the third node N3 illustrated in Math. 2, and ΔSGL3 may represent the amount of change in voltage of the third sub-gate line SGL3 (that is, the amount of voltage increased from the low-level voltage to the high-level voltage).

Referring to Math. 4, the voltage VN3′ of the third node N3 during the fourth period T4 may be increased by a predetermined voltage corresponding to the amount of change in voltage of the third sub-gate line SGL3. In this case, the voltage Vdata of the data signal supplied during the first period T1 to the third period T3 may be set low.

For example, if the voltage of the third node N3 is not increased by the third sub-gate line SGL3, a voltage Vdata of a data signal of 3 V may be supplied to implement a predetermined grayscale. On the other hand, if the voltage of the third node N3 is increased by the third sub-gate line SGL3 as in the embodiments of the present disclosure, a voltage Vdata of a data signal lower than 3 V (for example, 2 V) may be supplied to implement a predetermined grayscale.

If the voltage Vdata of the data signal is lowered, the voltage applied to the first node N1 during the second period T2 may also be lowered. For example, during the second period T2, the voltage of the first node N1 is lowered to a voltage (Vdata+|Vth(M1)|) which is the sum of the voltage of the data signal Vdata and the absolute threshold voltage of the first transistor M1. Accordingly, when the voltage of the data signal Vdata is lowered, the voltage of the first node N1 may also be lowered.

When the voltage of the first node N1 is lowered, the threshold voltage of the first transistor M1 may be increased by the body effect of the first transistor M1. That is, during the second period T2, the threshold voltage Vth of the first transistor M1 expressed in Math. 2 increases, and accordingly, the threshold voltage compensation capability of the first transistor M1 may be relatively improved.

More specifically, as illustrated in Math. 2, the threshold voltage Vth of the first transistor M1 may be reflected to the third node N3 in response to the ratio of the capacitor (for example, C1/(C1+C2+C3)). In this case, the threshold voltage Vth of the first transistor M1 may not be fully reflected to the third node N3, and thus, the threshold voltage compensation capability may be reduced.

According to some embodiments of the present invention, the threshold voltage Vth of the first transistor M1 may be increased during the second period T2 to compensate for the loss of the threshold voltage Vth due to the ratio of the capacitor (for example, C1/(C1+C2+C3)). That is, according to some embodiments of the present invention, during the second period T2 in which the threshold voltage Vth of the first transistor M1 is compensated, the threshold voltage Vth of the first transistor M1 is increased, and thus the threshold voltage Vth of the first transistor M1 may be stably compensated.

According to some embodiments, according to some embodiments of the present invention, the voltage Vdata of the data signal may be reflected in the driving current in accordance with the ratio of the capacitors. When the voltage Vdata of the data signal is reflected in the driving current in accordance with the ratio of the capacitors, the voltage range of the data signal may be widened.

For example, when the voltage Vdata of the data signal is directly reflected in the driving current, the voltage range of the data signal is set low. In this case, it is difficult to implement the grayscale using a data signal with a low voltage range, and is thus difficult to stably implement the desired grayscale. On the other hand, when the voltage range of the data signal is set wide as in the embodiments of the present invention, the grayscale may be stably implemented.

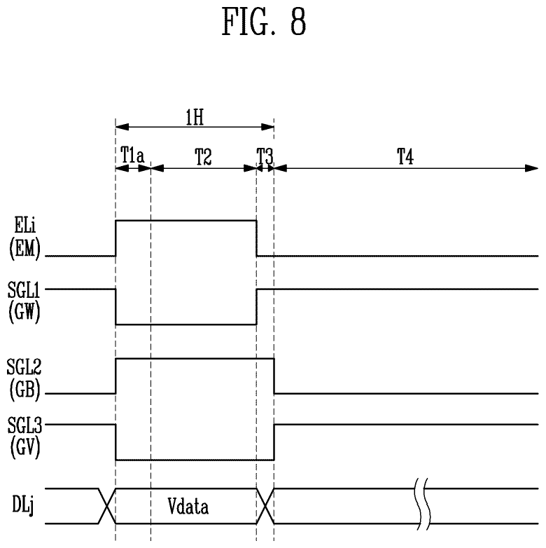

FIG. 8 is a waveform diagram illustrating aspects of the method for driving the sub-pixels illustrated in FIGS. 4 and 5 according to some embodiments. When describing FIG. 8, some description overlapping with FIG. 6 may be omitted.

Referring to FIG. 8, the horizontal period 1H (or specific horizontal period) in which the sub-pixel SPij is driven may be divided into a first period T1a, a second period T2, and a third period T3.

The data driver 130 may supply the voltage Vdata of the data signal to the data line DLj during the first period T1a to the third period T3.

The gate driver 120 (or the first gate driver 122) may supply the first scan signal GW to the first sub-gate line SGL1 during the first period T1 and the second period T2. The first scan signal GW may be a logic low level.

The gate driver 120 (or the second gate driver 124) may supply a second scan signal GB to the second sub-gate line SGL2 during the first period T1 to the third period T3. The second scan signal GB may be a logic high level.

The gate driver 120 (or the third gate driver 126) may supply a third scan signal GV to the third sub-gate line SGL3 during the first period T1 to the third period T3. The third scan signal GV may be a logic low level.

The gate driver 120 (or the emission driver 128) may supply a disable emission control signal EM to the emission control line ELi during the first period T1a and the second period T2. The disable emission control signal EM may be a logic high level.

When the disable emission control signal EM is supplied to the emission control line ELi during the first period T1a, the third transistor M3 may be turned off during the first period T1a. During the first period T1a, an initialization voltage VINT may be supplied to the second node N2, and a voltage Vdata of a data signal may be supplied to the third node N3. According to some embodiments, during the first period T1a, the voltage of the first node N1 may be gradually lowered from the first power supply voltage VDD. For example, during the first period Ta (and the second period T2), the voltage of the first node N1 may be lowered from the first power supply voltage VDD to the voltage (Vdata+|Vth(M1)|) which is the sum of the voltage Vdata of the data signal and the absolute threshold voltage of the first transistor M1.

That is, in the method for driving the sub-pixel illustrated in FIGS. 4 and 5, the threshold voltage of the first transistor M1 is additionally compensated during the first period T1a, but the actual operation process may be the same as the driving method in FIG. 6.

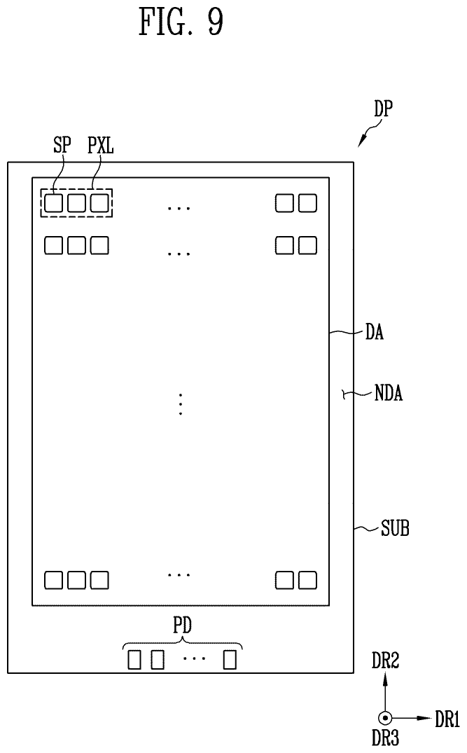

FIG. 9 is a plan view illustrating aspects of the display panel in FIG. 1 according to some embodiments.

Referring to FIG. 9, the embodiment DP of the display panel 110 in FIG. 1 may include a display area DA and a non-display area NDA. The display panel DP displays an image through the display area DA. The non-display area NDA is arranged around (e.g., in a periphery or outside a footprint of) the display area DA.

The display panel DP may include a substrate SUB, sub-pixels SP, and pads PD.

When the display panel DP is used as a display screen for a head mounted display (HMD), a virtual reality (VR) device, a mixed reality (MR) device, an augmented reality (AR) device, and the like, the display panel DP may be positioned very close to the user's eyes. In this case, sub-pixels SP with a relatively high degree of integration are required. In order to increase the degree of integration of the sub-pixels SP, the substrate SUB may be provided as a silicon substrate. On the substrate SUB, which is a silicon substrate, the sub-pixels SP and/or the display panel DP may be formed. A display device (100 in FIG. 1) including a display panel DP formed on a substrate SUB, which is a silicon substrate, may be referred to as an OLEDOS (OLED on Silicon) display device.

Sub-pixels SP are arranged in a display area DA on the substrate SUB. The sub-pixels SP may be arranged in a matrix form along a first direction DR1 and a second direction DR2 intersecting the first direction DR1. However, the embodiments are not limited thereto. For example, the sub-pixels SP may be arranged in a zigzag form along the first direction DR1 and the second direction DR2. For example, the sub-pixels SP may be arranged in a PENTILE® form or arrangement. The first direction DR1 may be a row direction, and the second direction DR2 may be a column direction.

Two or more sub-pixels among the plurality of sub-pixels SP may form one pixel PXL.

A component for controlling the sub-pixels SP may be arranged in a non-display area NDA on the substrate SUB. For example, wirings connected to the sub-pixels SP, such as the first to m-th gate lines GL1 to GLm and the first to n-th data lines DL1 to DLn in FIG. 1, may be arranged in the non-display area NDA.

At least one of the gate driver 120, the data driver 130, the voltage generator 140, the controller 150, or the temperature sensor 160 in FIG. 1 may be integrated in the non-display area NDA of the display panel DP. According to some embodiments, the gate driver 120 in FIG. 1 may be mounted on the display panel DP and located in the non-display area NDA. According to some embodiments, the gate driver 120 may be implemented as an integrated circuit separate from the display panel DP.

According to some embodiments, the temperature sensor 160 may be located in the non-display area NDA to detect the temperature of the display panel DP.

Pads PD are located in the non-display area NDA on the substrate SUB. The pads PD may be electrically connected to the sub-pixels SP through wirings. For example, the pads PD may be connected to the sub-pixels SP through the first to n-th data lines DL1 to DLn.

The pads PD may interface the display panel DP to other components of the display device (100 in FIG. 1). According to some embodiments, voltages and signals required for the operation of components included in the display panel DP may be provided from the driver-integrated circuit DIC in FIG. 1 through pads PD. For example, the first to n-th data lines DL1 to DLn may be connected to the driver-integrated circuit DIC through pads PD. For example, the first and second power supply voltages VDD and VSS may be received from the voltage generator 140 through pads PD. For example, when the gate driver 120 is mounted on the display panel DP, the gate control signal GCS may be transmitted from the driver-integrated circuit DIC to the gate driver 120 through pads PD.

According to some embodiments, the circuit board may be electrically connected to the pads PD using a conductive adhesive such as an anisotropic conductive film. At this time, the circuit board may be a flexible circuit board (FPCB) or a flexible film having a flexible material. The driver-integrated circuit DIC may be mounted on the circuit board and electrically connected to the pads PD.

According to some embodiments, the display area DA may have various shapes. The display area DA may have a shape of a closed loop including straight and/or curved sides. For example, the display area DA may have shapes such as a polygon, a circle, a semicircle, an ellipse, and the like.

According to some embodiments, the display panel DP may have a flat display surface. According to some embodiments, the display panel DP may have a display surface that is at least partially rounded. According to some embodiments, the display panel DP may be bendable, foldable, or rollable. In these cases, the display panel DP and/or the substrate SUB may include materials having flexible properties.

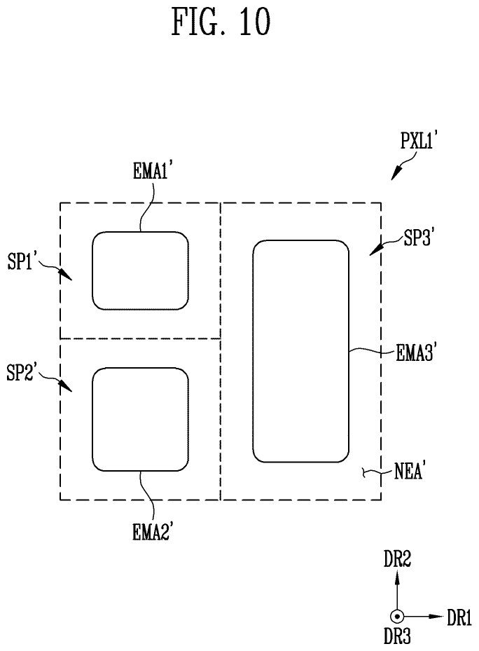

FIG. 10 is a plan view illustrating aspects of one of the pixels in FIG. 9 according to some embodiments.

Referring to FIG. 10, the first pixel PXL1′ may include first to third sub-pixels SP1′ to SP3′.

The first sub-pixel SP1′ may include a first emission area EMA1′ and a non-emission area NEA′ surrounding the first emission area EMA1′. The second sub-pixel SP2′ may include a second emission area EMA2′ and a non-emission area NEA′ surrounding the second emission area EMA2′. The third sub-pixel SP3′ may include a third emission area EMA3′ and a non-emission area NEA′ surrounding the third emission area EMA3′.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

The second sub-pixel SP2′ may have a larger area than the first sub-pixel SP1′, and the third sub-pixel SP3′ may have a larger area than the second sub-pixel SP2′. Accordingly, the second emission area EMA2′ may have a larger area than the first emission area EMA1′, and the third emission area EMA3′ may have a larger area than the second emission area EMA2′. However, the embodiments are not limited thereto. For example, the first and second sub-pixels SP1′ and SP2′ may have substantially the same area, and the third sub-pixel SP3′ may have a larger area than each of the first and second sub-pixels SP1′ and SP2′. In this way, the areas of the first to third sub-pixels SP1′ to SP3′ may be variously modified according to the embodiments.

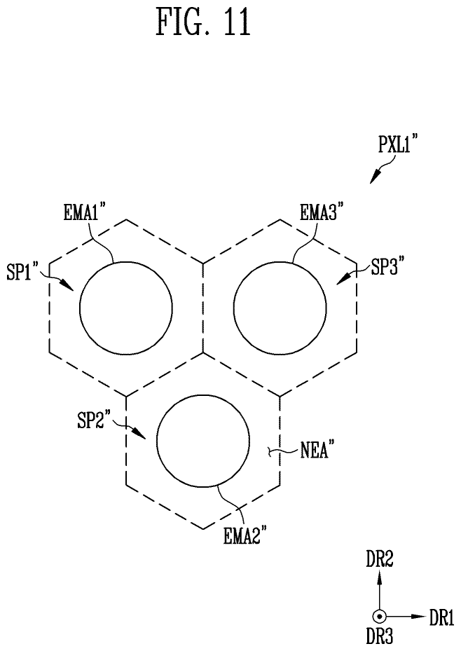

FIG. 11 is a plan view illustrating aspects of one of the pixels in FIG. 9 according to some embodiments.

Referring to FIG. 11, the first sub-pixel SP1″ may include a first emission area EMA1″ and a non-emission area NEA″ surrounding the first emission area EMA1″. The second sub-pixel SP2″ may include a second emission area EMA2″ and a non-emission area NEA″ surrounding the second emission area EMA2″. The third sub-pixel SP3″ may include a third emission area EMA3″ and a non-emission area NEA″ surrounding the third emission area EMA3″.

The first to third sub-pixels SP1″ to SP3″ may have polygonal shapes when viewed in the third direction DR3. For example, the shapes of the first to third sub-pixels SP1″ to SP3″ may be hexagons as illustrated in FIG. 11.

The first to third emission areas EMA1″ to EMA3″ may have circular shapes when viewed in the third direction DR3. However, the embodiments are not limited thereto. For example, each of the first to third emission areas EMA1″ to EMA3″ may have a polygonal shape.

The first and third sub-pixels SP1″ and SP3″ may be arranged in the first direction DR1. The second sub-pixel SP2″ may be arranged in a direction (or diagonal direction) that is inclined at an acute angle with respect to the second direction DR2 with respect to the first sub-pixel SP1″.

The above arrangement of sub-pixels is an example, and embodiments are not limited thereto. Each pixel includes two or more sub-pixels, and the sub-pixels may be arranged in various ways, each of the sub-pixels may have various shapes, and each of its emission areas may also have various shapes.

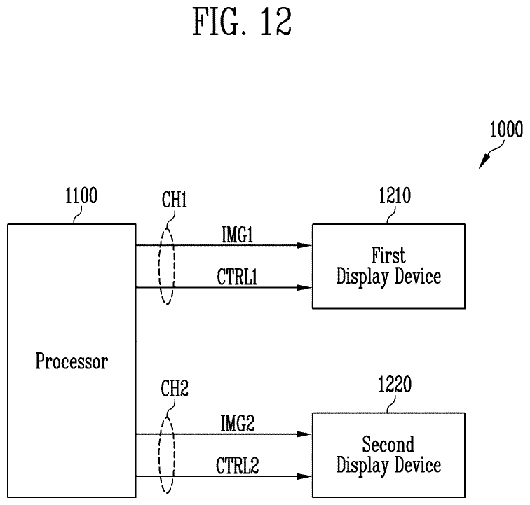

FIG. 12 is a block diagram illustrating aspects of a display system according to some embodiments.

Referring to FIG. 12, a display system 1000 may include a processor 1100 and one or more display devices 1210 and 1220.

The processor 1100 may perform various tasks and calculations. According to some embodiments, the processor 1100 may include an application processor, a graphic processor, a microprocessor, a central processing unit (CPU), and the like. The processor 1100 may be connected to other components of the display system 1000 through a bus system and control them.

In FIG. 12, the display system 1000 is illustrated as including first and second display devices 1210 and 1220. The processor 1100 may be connected to the first display device 1210 through a first channel CH1 and to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this case, the first image data IMG1 and the first control signal CTRL1 may be provided as the input image data IMG and the control signal CTRL in FIG. 1, respectively.

Through the second channel CH2, the processor 1100 may transmit the second image data IMG2 and the second control signal CTRL2 to the second display device 1220. The second display device 1220 may display an image based on the second image data IMG2 and the second control signal CTRL2. The second display device 1220 may be configured similarly to the display device 100 described with reference to FIG. 1. In this case, the second image data IMG2 and the second control signal CTRL2 may be provided as the input image data IMG and the control signal CTRL in FIG. 1, respectively.

The display system 1000 may include a computing system that provides an image display function, such as a portable computer, a mobile phone, a smartphone, a tablet personal computer, a smartwatch, a watch phone, a portable multimedia player (PMP), a navigation device, an ultra-mobile personal computer (UMPC), and the like. According to some embodiments, the display system 1000 may include at least one of a head mounted display (HMD), a virtual reality (VR) device, a mixed reality (MR) device, or an augmented reality (AR) device.

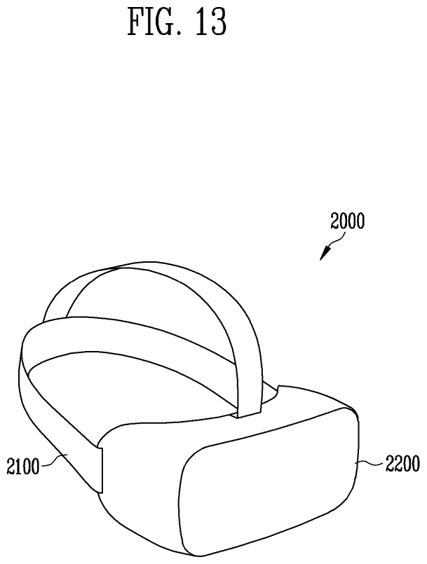

FIG. 13 is a perspective view illustrating an application example of the display system in FIG. 12.

Referring to FIG. 13, the display system 1000 in FIG. 19 may be applied to a head-mounted display device 2000. The head-mounted display device 2000 may be a wearable electronic device that may be worn on a user's head.

The head-mounted display device 2000 may include a head-mounted band 2100 and a display device storage case 2200. The head-mounted band 2100 may be connected to the display device storage case 2200. The head-mounted band 2100 may include a horizontal band and/or a vertical band for fixing the head-mounted display device 2000 to the user's head. The horizontal band may be configured to surround the side of the user's head, and the vertical band may be configured to surround the upper part of the user's head. However, the embodiments are not limited thereto. For example, the head-mounted band 2100 may be implemented in a form of a glasses frame, a helmet, or the like.

The display device storage case 2200 may store the first and second display devices 1210 and 1220 in FIG. 12. The display device storage case 2200 may further store the processor 1100 in FIG. 12.

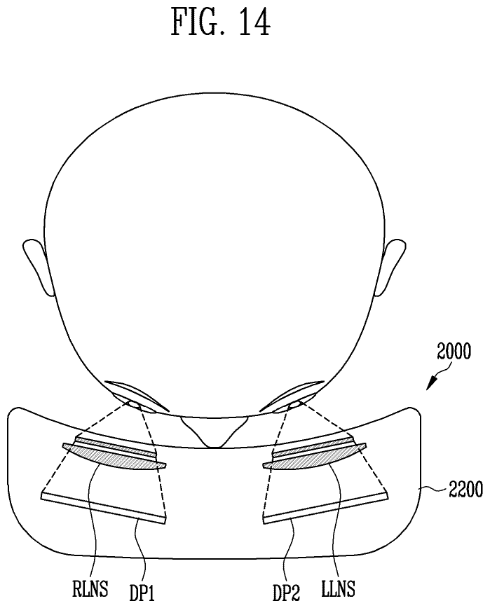

FIG. 14 is a drawing illustrating a head-mounted display device worn by a user.

Referring to FIG. 14, a first display panel DP1 of a first display device 1210 and a second display panel DP2 of a second display device 1220 are arranged in the head-mounted display device 2000. The head-mounted display device 2000 may further include one or more lenses LLNS and RLNS.

Within the display device storage case 2200, the right-eye lens RLNS may be located between the first display panel DP1 and the user's right eye. Within the display device storage case 2200, the left-eye lens LLNS may be located between the second display panel DP2 and the user's left eye.

An image output from the first display panel DP1 may be shown to the user's right eye through the right-eye lens RLNS. The right-eye lens RLNS may refract light from the first display panel DP1 toward the user's right eye. The right-eye lens RLNS may perform an optical function for adjusting the viewing distance between the first display panel DP1 and the user's right eye.

An image output from the second display panel DP2 may be shown to the user's left eye through the left-eye lens LLNS. The left-eye lens LLNS may refract light from the second display panel DP2 toward the user's left eye. The left-eye lens LLNS may perform an optical function for adjusting the viewing distance between the second display panel DP2 and the user's left eye.

According to some embodiments, each of the right-eye lens RLNS and the left-eye lens LLNS may include an optical lens having a pancake-shaped cross-section. According to some embodiments, each of the right-eye lens RLNS and the left-eye lens LLNS may include a multi-channel lens including sub-regions having different optical characteristics. In this case, each display panel outputs images corresponding to the sub-regions of the multi-channel lens, and the output images may be shown to the user by passing through the corresponding sub-regions.

Although aspects of some embodiments of the present disclosure have been described herein, other embodiments and variations may be derived from the above teachings. Accordingly, the spirit and scope of embodiments according to the present disclosure are not limited to these embodiments, but extends to the scope of the appended claims, and their equivalents.

What is claimed is:

1. A sub-pixel comprising:
a first transistor having a first electrode connected to a first power supply voltage node configured to receive a first power supply voltage via a first node, a second electrode connected to a second node, and a gate electrode connected to a third node;
a light-emitting element connected between the second node and a second power supply voltage node configured to receive a second power supply voltage;
a second transistor connected between a data line and the third node and having a gate electrode connected to a first sub-gate line;
a first capacitor connected between the first node and the third node;
a second capacitor connected between the third node and a voltage control line; and
a third capacitor connected between the third node and the second node.

2. The sub-pixel of claim 1, wherein
the voltage control line is configured to have a low-level voltage based on a data signal from the data line being supplied to the third node and to have a high-level voltage higher than the low-level voltage based on the data signal not being supplied to the third node.

3. The sub-pixel of claim 1, further comprising:
a third transistor connected between the first power supply voltage node and the first node and having a gate electrode connected to an emission control line; and
a fourth transistor connected between the second node and an initialization voltage node configured to receive an initialization voltage and having a gate electrode connected to a second sub-gate line.

4. The sub-pixel of claim 3, wherein
the voltage control line is configured to have a low-level voltage during a period in which the fourth transistor is turned on and to have a high-level voltage higher than the low-level voltage during a period in which the fourth transistor is turned off.

5. The sub-pixel of claim 4, wherein
the second transistor is configured to be turned on during a part of a period in which the fourth transistor is turned on.

6. The sub-pixel of claim 3, wherein
the first transistor, the second transistor, and the third transistor are P-type transistors, and the fourth transistor is an N-type transistor.

7. The sub-pixel of claim 6, wherein
each of the first transistor to the fourth transistor includes a body electrode, and
the body electrode of each of the first transistor to the third transistor is configured to receive the first power supply voltage, and the body electrode of the fourth transistor is configured to receive the initialization voltage.

8. The sub-pixel of claim 6, wherein
each of the first transistor to the fourth transistor includes a body electrode, and
the body electrode of each of the first transistor to the third transistor is configured to receive the first power supply voltage, and the body electrode of the fourth transistor is configured to receive a ground voltage.

9. The sub-pixel of claim 3, wherein
one horizontal period is divided into a first period, a second period, and a third period,
the second transistor is configured to be turned on during the first period and the second period,
the fourth transistor is configured to be turned on during the first period to the third period,
the third transistor is configured to be turned off during the second period, and
the voltage control line has a low-level voltage during the first period to the third period and has a high-level voltage higher than the low-level voltage during other periods.

10. The sub-pixel of claim 9, wherein
the data line is configured to receive a data signal during the first period to the third period.

11. The sub-pixel of claim 9, wherein
the third transistor is further configured to be turned off during the first period.

12. A display device comprising:
a sub-pixel connected to data lines, gate lines, and emission control lines;
a gate driver configured to drive the gate lines and the emission control lines; and
a data driver configured to drive the data lines, wherein
each of the sub-pixels comprises:
a first transistor having a first electrode connected to a first power supply voltage node configured to receive a first power supply voltage via a first node, a second electrode connected to a second node, and a gate electrode connected to a third node;
a light-emitting element connected between the second node and the second power supply voltage node configured to receive a second power supply voltage;
a second transistor connected between a data line, which is one of the data lines, and the third node and having a gate electrode connected to a first sub-gate line, which is one of the gate lines;
a first capacitor connected between the first node and the third node;
a second capacitor connected between the third node and a voltage control line, which is one of the gate lines; and
a third capacitor connected between the third node and the second node.

13. The display device of claim 12, wherein
each of the sub-pixels further comprises:
a third transistor connected between the first power supply voltage node and the first node and having a gate electrode connected to an emission control line which is one of the emission control lines; and
a fourth transistor connected between the second node and an initialization voltage node configured to receive an initialization voltage and having a gate electrode connected to a second sub-gate line which is one of the gate lines.

14. The display device of claim 13, wherein
the first transistor, the second transistor, and the third transistor are P-type transistors, and the fourth transistor is an N-type transistor.

15. The display device of claim 14, wherein
each of the first to fourth transistors includes a body electrode, and
the body electrode of each of the first to third transistors is configured to receive the first power supply voltage, and the body electrode of the fourth transistor is configured to receive one of the initialization voltage and a ground voltage.

16. The display device of claim 15, wherein
one horizontal period is divided into a first period, a second period, and a third period, and
the gate driver is configured to:
supply a first scan signal having a gate-on voltage to the first sub-gate line during the first period and the second period;
supply a second scan signal having a gate-on voltage to the second sub-gate line during the first period to the third period;
supply a low-level voltage to the voltage control line during the first period to the third period; and
supply an emission control signal having a gate-off voltage to the emission control line during the second period.

17. The display device of claim 16, wherein
the gate driver is configured to supply a high-level voltage higher than the low-level voltage to the voltage control line during a period other than the first period to the third period.

18. The display device of claim 16, wherein
the gate driver further is configured to supply the emission control signal to the emission control line during the first period.

19. The display device of claim 16, wherein
the data driver is configured to supply a data signal to the data line during the first period to the third period.

20. An electronic device, comprising
a processor to provide image data;
a display device to display an image based on the image data; and
wherein the display device, comprising:
a sub-pixel connected to data lines, gate lines, and emission control lines;
a gate driver configured to drive the gate lines and the emission control lines; and
a data driver configured to drive the data lines, wherein
each of the sub-pixels comprises:
a first transistor having a first electrode connected to a first power supply voltage node configured to receive a first power supply voltage via a first node, a second electrode connected to a second node, and a gate electrode connected to a third node;
a light-emitting element connected between the second node and the second power supply voltage node configured to receive a second power supply voltage;
a second transistor connected between a data line, which is one of the data lines, and the third node and having a gate electrode connected to a first sub-gate line, which is one of the gate lines;
a first capacitor connected between the first node and the third node;
a second capacitor connected between the third node and a voltage control line, which is one of the gate lines; and
a third capacitor connected between the third node and the second node.
